(19) United States
(12) Patent Application Publication
(10) Pub. No.: US 2006/0107191 A1
(43) Pub. Date: May 18, 2006

(54) Program development support system, program development support method and the program thereof

(76) Inventors: Takashi Hirooka, Sagamihara (JP); Chiaki Hirai, Tokyo (JP); Hiroji Shibuya, Odawara (JP); Masao Mougi, Atsugi (JP); Takahisa Kimura, Odawara (JP); Jun Shimabukuro, Yokohama (JP); Erika Ayukawa, Tokyo (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/033,627

(22) Filed: Jan. 13, 2005

(30) Foreign Application Priority Data
Oct. 18, 2004 (JP) 2004-302532

(51) Int. Cl. H03M 13/03

(52) U.S. Cl. 714/796

(57) ABSTRACT

Development of a program is supported by presenting importance of each part of the program. A program development support system comprises: a metrics information storage part 32 that stores metrics information for each part of the program, with the metrics information indicating complexity of the part in question in relation to other parts of the program; a failure information storage means 34 that stores failure information for each failure occurring in the program, with said failure information indicating a corrected part of the program to cope with the failure and influence of the failure on a program user; a failure correction difficulty analysis part 23 and an importance determination part 24 that determine importance of each part of the program, using the complexity indicated by the metrics information of the part in question and the influence indicated by the failure information of each failure against which the part in question is to be corrected as a countermeasure, with the importance indicating a size of program development man-hours to be allocated to the part in question; and an input/output part 1 that outputs the determined importance of each part of the program.

### CLAIM OF PRIORITY

The present application claims priority from Japanese application P2004-302532 filed on Oct. 18, 2004, the content of which is hereby incorporated by reference into this application.

### FIELD OF THE INVENTION

The present invention relates to a technique of supporting program development.

### BACKGROUND OF THE INVENTION

As a technique of supporting understanding of a program, there is a technique called re-engineering for visualizing program structure of a source program. For example, in the case of re-engineering described in Japanese Non-examined Laid-Open No. 5-313870 (hereinafter, referred to as Patent Document 1), a source program is analyzed to generate program instruction analysis information and comment part analysis information. Then, from the generated program instruction analysis information and comment part analysis information, is generated program structure element information that specifies program structure elements. Further, from the program structure element information, is generated a program structure diagram on which comments in the source program are reflected appropriately. Thus, it is possible to express an outline and meaning of the source program without directly expressing individual instructions of the source program in detail, and the source program becomes more understandable.

Further, there is a technique called knowledge management for sharing information (knowledge) required for work. For example, knowledge management described in Japanese Non-examined Laid-Open No. 2004-62707 (hereinafter, referred to as Patent Document 2) generates a common template and a differential template. The common template defines common items in working such as working procedures, programs, know-how and the like, while the differential template is generated as information that is not defined in the common template. Knowledge is accumulated by accumulating new information in the work carried out using the common template in the differential template. It is also possible to generate failure information that indicates countermeasures used against similar past failures accumulated as the knowledge. By presenting failure information to a program developer, it is possible to support devising of program failure prevention measures.

Generally speaking, a computer program has a different use frequency and complexity at each part of the program. However, the above-described re-engineering and knowledge management do not consider this fact. Accordingly, when these techniques are used for supporting program development, a program developer spends the same man-hours for performing analysis, changes, verification and the like of a more important part (i.e., parts that have a high probability of failure occurrence or that are greatly affected by modification) of a program as a less important part. Thus, this results in man-hour shortage for developing a more important part and man-hour excess for developing a less important part. Further, in the case where there exist a plurality of countermeasures against a certain failure in a program under development and each countermeasure means a modification of a different part of the program, it is possible that a developer of the program modifies a more important part of the program and, as a result, man-hours needed for future development or maintenance becomes larger.

### SUMMARY OF THE INVENTION

The present invention has been made taking the above-described circumstances into consideration, and an object of the present invention is to support program development, by presenting importance of each part of a program.

To solve the above problem, the present invention analyzes a source program to generate, for each part of the program, metrics information that indicates influence of that part on other parts. Further, program's failure report document data are analyzed to generate, for each failure, failure information that indicates a corrected part of the program to cope with the failure and influence of the failure on a user of the program. Then, for each part of the program, importance that indicates a size of program development man-hours to be allocated to that part is determined based on the metrics information of the part in question and the failure information of a failure against which the part in question is corrected.

For example, the present invention provides a program development support system, which supports development of a program, comprising: a metrics information storing means that stores metrics information for each part of the program, the metrics information indicating complexity of the part in relation to other parts of the program; a failure information storing means that stores failure information for each failure occurring in the program, the failure information indicating a corrected part of the program to cope with the failure and influence of the failure on a program user; an operation means that determines importance of each part of the program, using the complexity indicated by the metrics information of the part in question and the influence indicated by the failure information of each failure against which the part in question is to be corrected as a countermeasure, the importance indicating a size of program development man-hours to be allocated to the part in question; and an importance output means that outputs the importance determined by the operation means for each part of the program.

According to the present invention, for each part of a program, importance indicating a size of program development man-hours to be allocated is determined. Even then a program developer designs a program with the same total development man-hours in comparison with the conventional methods, it is possible to reduce failures that have large effects by using more man-hours for more important parts in the program. Accordingly, a high quality program can be developed. Further, it is possible to select a failure countermeasure that corrects less important parts of a program, and as a result, it is possible to reduce the probability of future increase of development and maintenance man-hours.

### BRIEF DESCRIPTION OF THE DRAWINGS

FIG. 1 is a schematic diagram showing a program development support system to which one embodiment of the present invention is applied;

FIG. 2 shows an example of a source program written in a high-level language;

FIG. 3 is a diagram showing an example of a registration content of a function metrics information table 321;

FIG. 4 is a diagram showing an example of a registration content of a table metrics information table 322;

FIG. 5 shows an example of failure report document data;

FIG. 6 is a diagram showing an example of a registration content of a failure information table 341;

FIG. 7 is a diagram showing an example of a registration content of a failure correction difficulty information table 351;

FIG. 8 is a diagram showing an example of a function importance table 361;

FIG. 9 is a diagram showing an example of a hardware configuration of the program development support system;

FIG. 10 is a chart showing an operation flow of a program development support system to which one embodiment of the present invention is applied;

FIG. 11 is a flowchart for explaining source program analysis processing;

FIG. 12 is a flowchart for explaining failure report document analysis processing;

FIG. 13 is a flowchart for explaining failure correction difficulty analysis processing;

FIG. 14 is a flowchart for explaining importance determination processing; and

FIG. 15 shows an example of screen display of function importance.

### DESCRIPTION OF THE PREFERRED EMBODIMENTS

Now, will be described embodiments of the present invention.

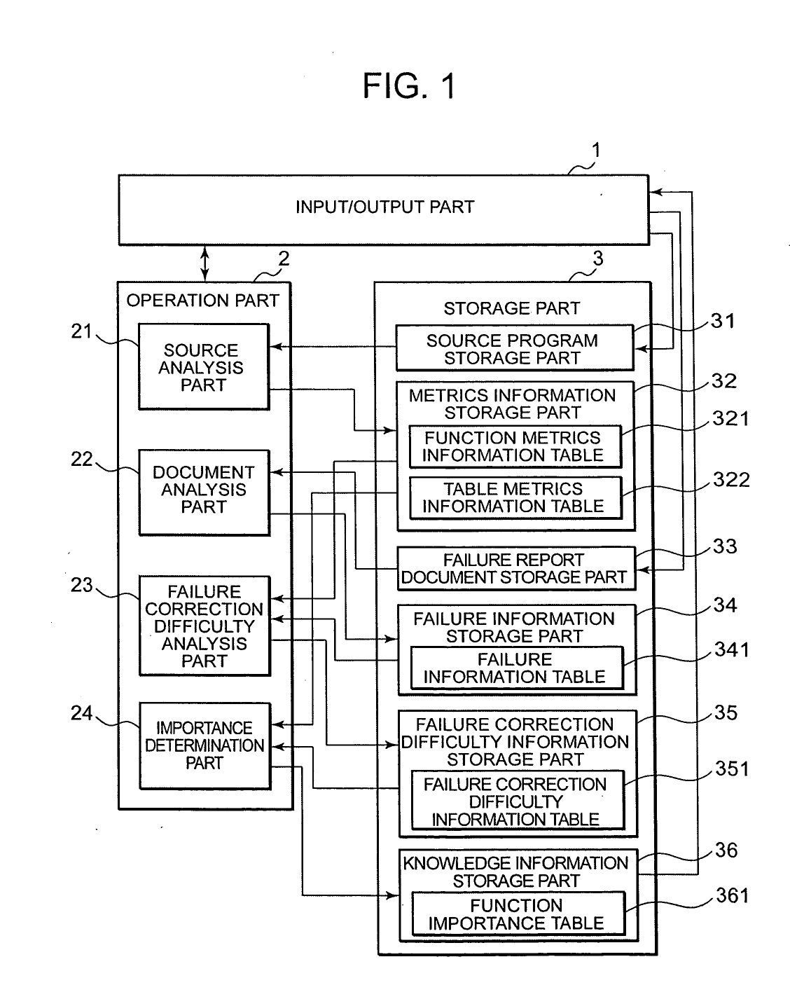

FIG. 1 is a schematic diagram showing a program development support system to which one embodiment of the present invention is applied.

The program development support system of the present embodiment receives, as its input, a source program and failure report document data that indicates failures of the source program generated from its development process, and outputs a piece of knowledge, namely, importance of (i.e., a size of program development man-hours to be allocated to) each of functions constituting the program. As shown in the figure, the program development support system comprises an input/output part 1, an operation part 2, and a storage part 3.

The input/output part 1 receives, as its input, various pieces of information including the source program and the failure report document data, and instructions of a user (a program developer), and outputs the knowledge including the importance of each function as a constituent of the program and other information.

The storage part 3 comprises a source program storage part 31, a metrics information storage part 32, a failure report document storage part 33, a failure information storage part 34, a failure correction difficulty information storage part 35, and a knowledge information storage part 36.

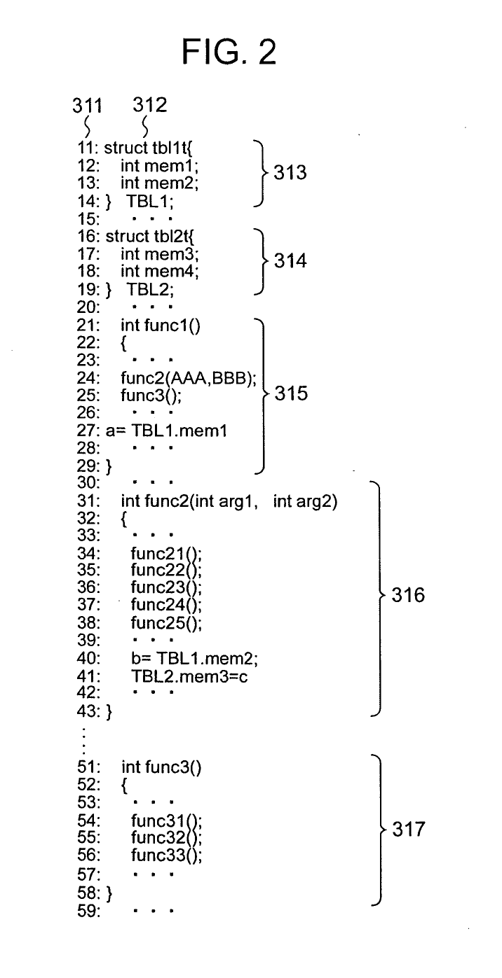

The source program storage part 31 stores the source program inputted into the input/output part 1. FIG. 2 shows an example of the source program written in a high-level programming language. In this figure, the reference numeral 311 indicates line numbers, and the reference numeral 312 indicates the written high-level programming language.

In the example of the source program shown in FIG. 2, a part 313 of 11th-14th lines and a part 314 of 16th-19th lines are respectively a declaration of a table “TBL1” and a declaration of a table “TBL2”. The part 313 declares in the 12th and 13th lines that the table “TBL1” includes elements “mem1” and “mem2”. Similarly, the part 314 declares in the 17th and 18th lines that the table “TBL2” includes elements “mem3” and “mem4”. Further, a part 315 of 21st-29th lines, a part 316 of 31st-43rd lines and a part 317 of 51st-58th lines are respectively declarations of functions “func1”, “func2” and “func3”. In the part 315, the 24th and 25th lines call the functions “func2” and “func3”. And, the 27th line assigns the element “mem1” of the table “TBL1” to “a” (Read Reference). In the part 316, the 34th -38th lines call functions “func21”-“func25”. And, the 40th line assigns the element “mem2” of the table “TBL1” to “b” (Read Reference). Further, the 41st line assigns “c” to the element “mem3” of the table “TBL2” (Write Reference). In the part 317, the 54th-56th lines call functions “func31”-“func33”.

The metrics information storage part 32 stores metrics information for each part of the source program. The metrics information indicates influence of the part in question on other parts. The metrics information storage part 32 has a function metrics information table 321 and a table metrics information table 322.

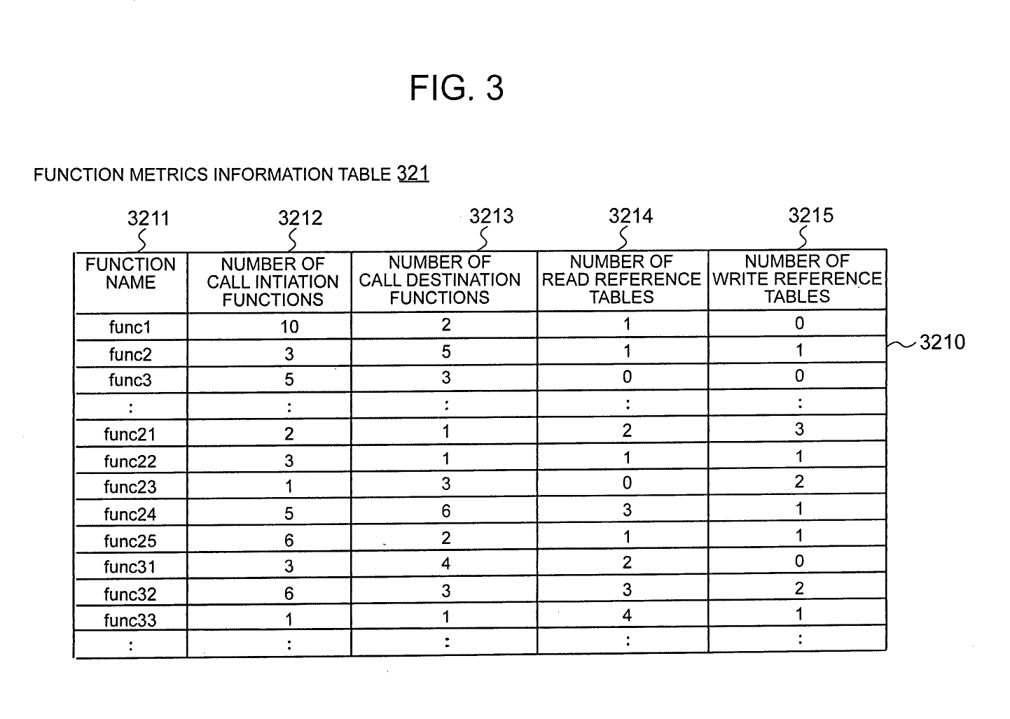

FIG. 3 is a diagram showing an example of a registration content of the function metrics information table 321. As shown in the figure, the function metrics information table 321 registers, for each function declared in the source program, a record 3210 of metrics information that indicates influence of the function upon other functions and tables. Each record 3210 includes a field 3211 which registers a name of a function, a field 3212 which registers the number of other functions (hereinafter, referred to as call initiation functions) that call the function in question, a field 3213 which registers the number of other functions (hereinafter, referred to as call destination functions) that are called by the function in question, a field 3214 which registers the number of tables (hereinafter, referred to as read reference tables) that are objects of Read Reference by the function in question, and a field 3215 which registers the number of tables (hereinafter, referred to as write reference tables) that are objects of Write Reference by the function in question.

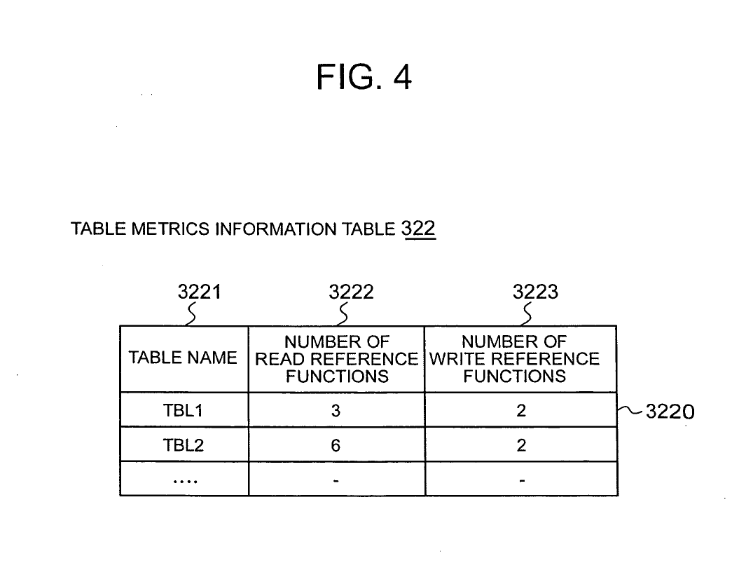

FIG. 4 is a diagram showing an example of a registration content of the table metrics information table 322. As shown in the figure, the table metrics information table 322 registers, for each table declared in the source program, a record 3220 of metrics information that indicates influence of the table upon functions. Each record 3220 includes a field 3221 which registers a name of a table, a field 3222 which registers the number of functions (hereinafter, referred to as read reference functions) for which the table in question becomes an object of Read Reference, and a field 3223 which registers the number of functions (hereinafter, referred to as write reference functions) for which the table in question becomes an object of Write Reference.

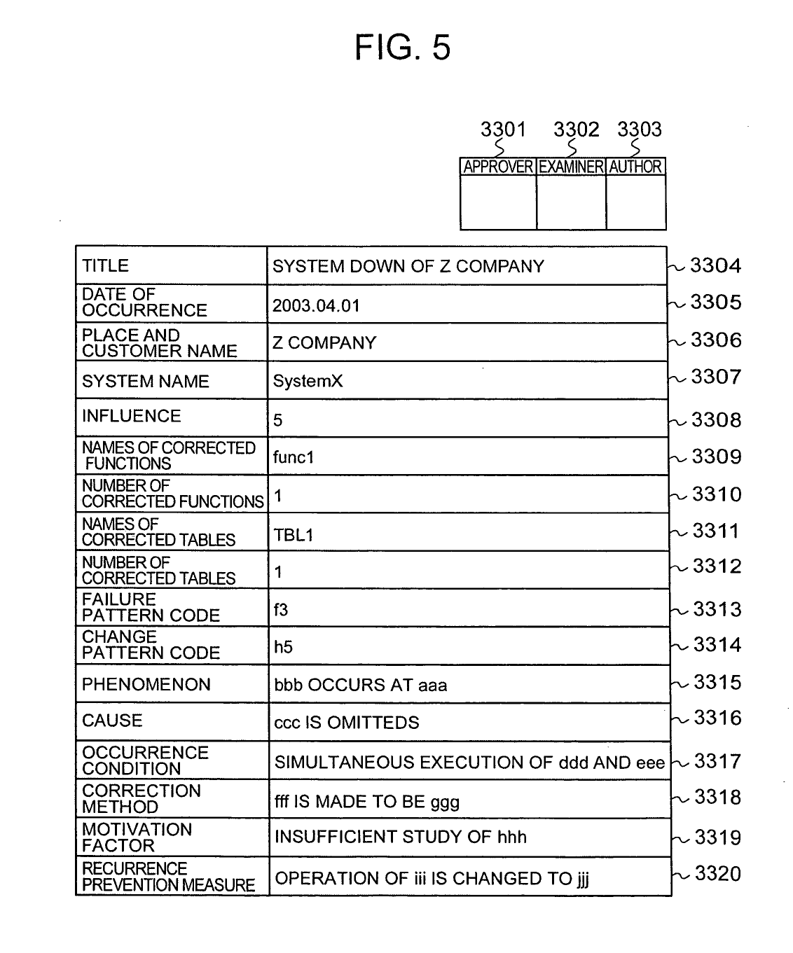

The failure report document storage part 33 stores failure report document data inputted into the input/output part 1. FIG. 5 shows an example of failure report document data. Failure report document data are generated for each failure of a program, which occurs in the development process of that program.

The example of failure report document data shown in FIG. 5 includes a field 3301 which registers information on an approver, a field 3302 which registers information on an examiner, a field 3303 which registers information on an author, a field 3304 which registers a title name of a failure, a field 3305 which registers a date of occurrence of the failure, a field 3306 which registers a name of a place or customer at which the failure has occurred, a field 3307 which registers a name of a system at which the failure has occurred, a field 3308 which registers influence (a degree of influence on the customer) of the failure, a field 3309 which registers names of functions corrected to cope with the failure, a field 3310 which registers the number of the functions corrected to cope with the failure, a field 3311 which registers names of tables corrected to cope with the failure, a field 3312 which registers the number of the tables corrected to cope with the failure, a field 3313 which registers a code of a failure type (a failure pattern), a field 3314 which registers a code of an anti-failure measure type (a change patter), a field 3315 which registers a phenomenon of the failure, a field 3316 which registers a cause of the failure, a field 3317 which registers a condition under which the failure occurs, a field 3318 which registers a method of correcting the failure, a field 3319 which registers a motivation factor of the failure, and a field 3320 which registers a recurrence prevention measure against the failure.

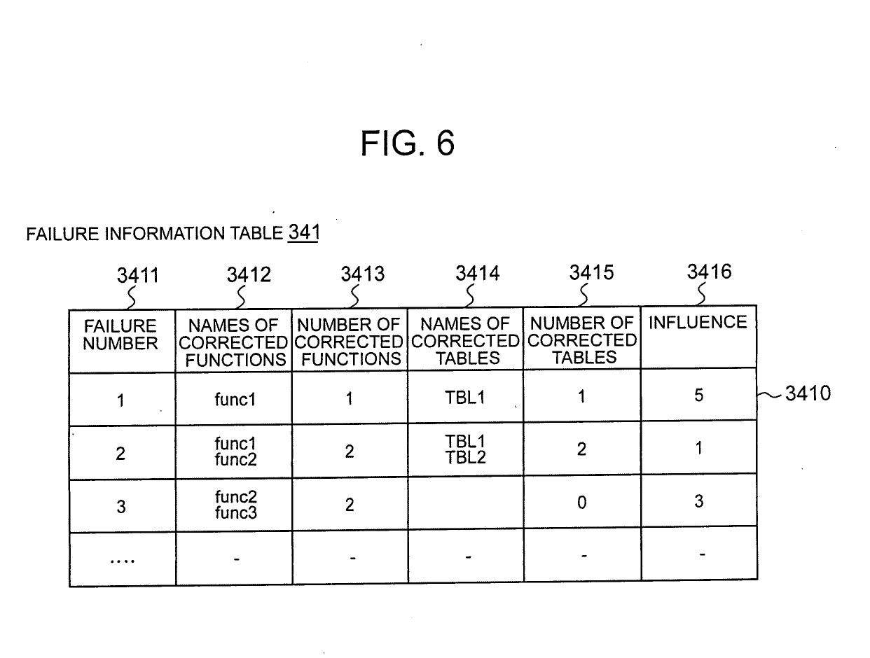

The failure information storage part 34 has a failure information table 341. FIG. 6 is a diagram showing an example of a registration content of the failure information table 341.

As shown in the figure, the failure information table 341 registers, for each failure of the program, a record 3410 of failure information that includes a program content corrected to cope with the failure and influence (a degree of influence on the customer) of the failure. Each record 3410 includes a field 3411 which registers a failure number uniquely given to each failure, a field 3412 which registers names of functions corrected to cope with the failure, a field 3413 which registers the number of the functions corrected to cope with the failure, a field 3414 which registers names of tables corrected to cope with the failure, a field 3415 which registers the number of tables corrected to cope with the failure, and a field 3416 which registers influence of the failure.

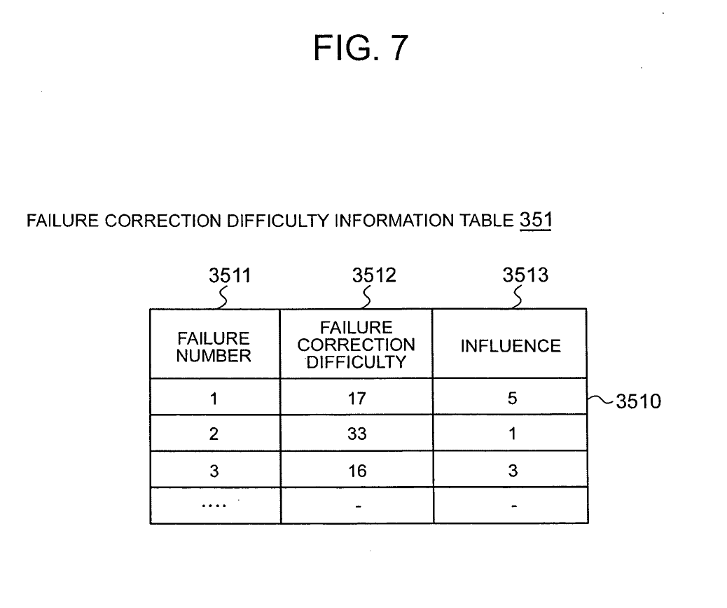

The failure correction difficulty information storage part 35 has a failure correction difficulty information table 351. FIG. 7 is a diagram showing an example of a registration content of the failure correction difficulty information storage table 351.

As shown in the figure, the failure correction difficulty information table 351 registers, for each failure of the program, a record 3510 of failure correction difficulty information that includes difficulty of failure correction and influence (a degree of influence on the customer) of the failure. Each record 3510 includes a field 3511 which registers a failure number, a field 3512 which registers difficulty of failure correction, and a field 3513 which registers influence of the failure concerned.

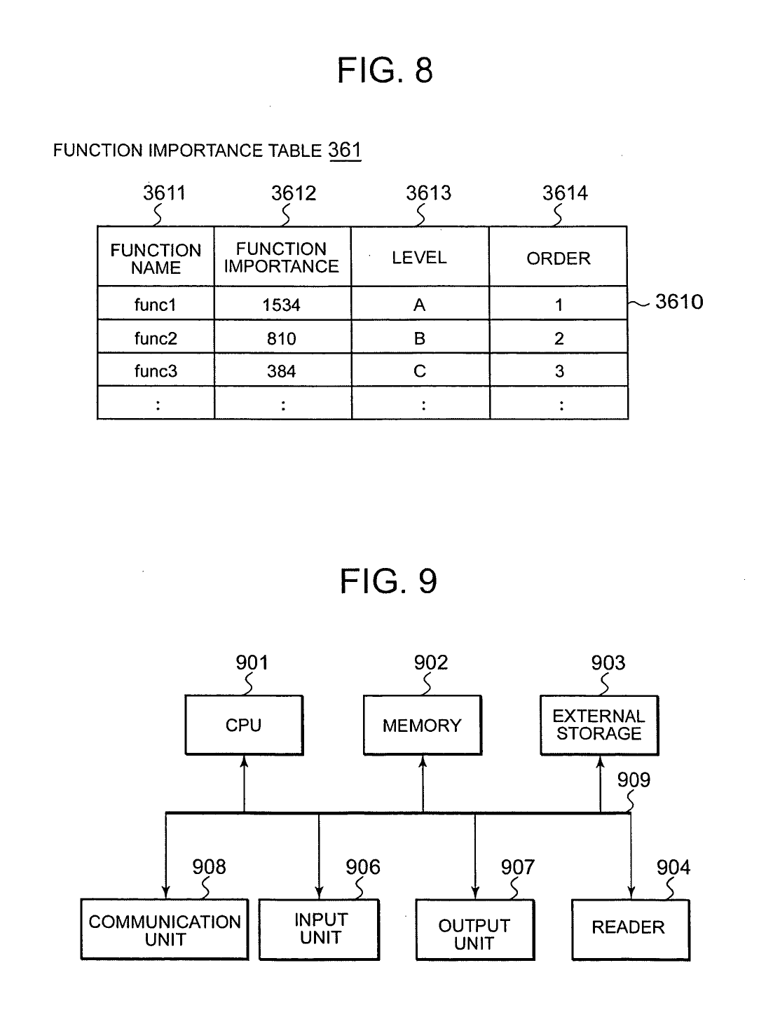

The knowledge information storage part 36 has a function importance table 361. FIG. 8 is a diagram showing an example of a registration content of the function importance table 361.

As shown in the figure, the function importance table 361 registers, for each function described in the program, a record 3610 of function importance information that includes importance of (i.e., a size of program development man-hours to be allocated to) the function. Each record 3610 includes a field 3611 which registers a name of a function, a field 3612 which registers importance of the function, a field 3613 which registers a general level to which the function's importance belongs, and a field 3614 which registers the order of man-hours to be allocated to the function.

Now, FIG. 1 is referred to again, to continue the description. The operation part 2 comprises a source analysis part 21 that analyzes the source program to generate metrics information, a document analysis part 22 that analyzes failure report document data to generate failure information, a failure correction difficulty analysis part 23 that uses the metrics information and the failure information to generate failure correction difficulty information, and an importance determination part 24 that uses the metrics information and the failure correction difficulty information to generate function importance information.

The program development support system having the above-described configuration can be realized on an ordinary computer system comprising, for example as shown in FIG. 9, a CPU 901, a memory 902, an external storage 903 such as an HDD or the like, a reader 904 which reads data from a storage medium such as a CD-ROM, a DVD-ROM, an IC card or the like, an input unit 906 such as a keyboard, a mouse or the like, an output unit 907 such as a monitor, a printer or the like, a communication unit 908 which connects with a network or the like, and a bus 909 connecting the mentioned component units, when the CPU 901 executes a program loaded on the memory 902. This program may be downloaded from a storage medium through the reader 904 or from the network through the communication unit 908 to the external storage 903, and then loaded onto the memory 902, to be executed by the CPU 901. Or, without through the external storage 903, the program may be directly loaded onto the memory 902 and executed by the CPU 901. In these cases, as the storage part 3, is used the memory 902 or the external storage 903. Further, as the input/output part 1, are used the reader 904, the input unit 906, the output unit 907 and the communication unit 908.

Next, will be described operation of the program development support system having the above configuration.

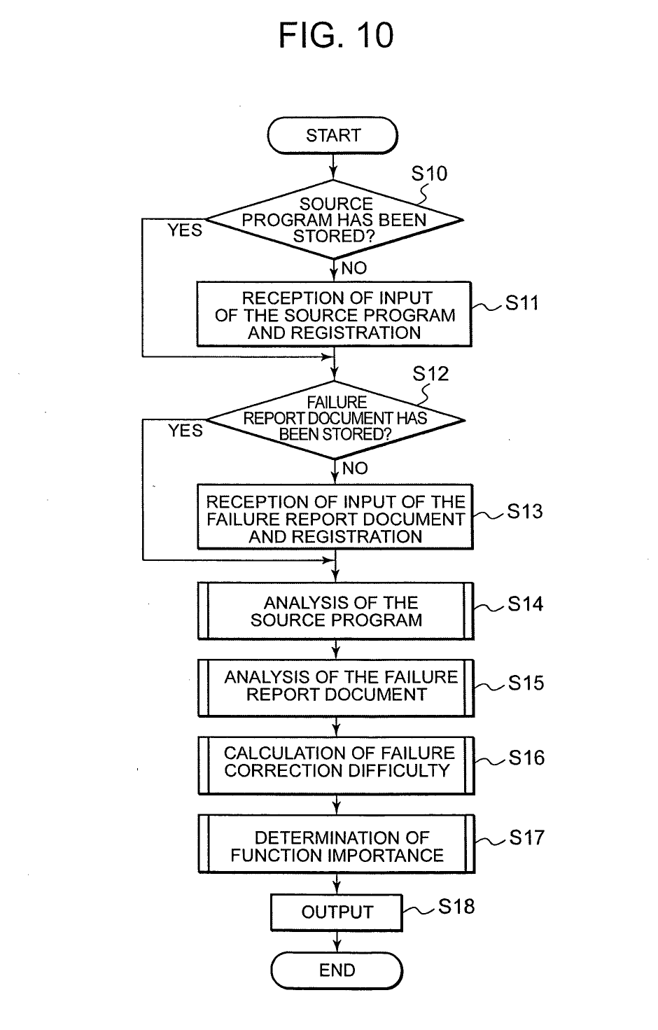

FIG. 10 is a chart for explaining an operation flow of the program development support system to which one embodiment of the present invention is applied. This flow is started when the input/output part 1 receives a program development support instruction from the user (program developer).

First, the input/output part 1 examines whether the source program storage part 31 stores a source program (S10). In the case where the source program storage part 31 does not store a source program, the input/output part 1 requests the user to input a source program. The inputted source program is stored into the source program storage part 31 (S11). Further, the input/output part 1 examines whether the failure report document storage part 33 stores at least one piece of failure report document data (S12). In the case where the failure report document storage part 33 does not store failure report document data, the input/output part 1 requests the user to input at least one piece of failure report document data. The inputted failure report document data is stored into the failure report document storage part 33 (S13).

Now, in the case where the source program storage part 31 stores the source program and the failure report document storage part 33 stores at least one piece of failure report document data, the source analysis part 21 performs source program analysis processing. Namely, the source analysis part 21 analyzes the source program to generate a function metrics information table 321 and a table metrics information table 322, and stores these tables 321 and 322 into the metrics information storage part 32 (S14).

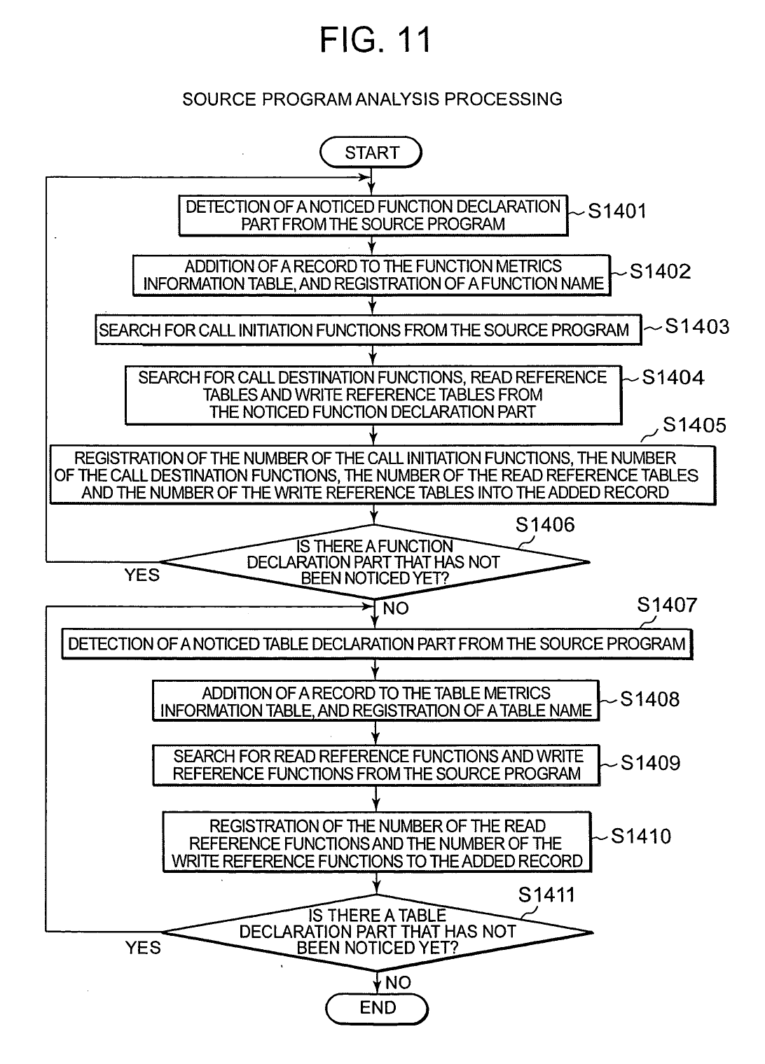

FIG. 11 is a flowchart for explaining the source program analysis processing.

First, the source analysis part 21 reads the source program from the source program storage part 31. Then, the source analysis part 21 detects a function declaration part that has not been noticed yet, from the source program, and determines the detected part as a noticed function declaration part (S1401). For example, in the case of the source program shown in FIG. 2, the part 315 declaring the function “func1” is first extracted as a noticed function declaration part. Next, the source analysis part 21 adds a record 3210 to the function metrics information table 321 (the number of records is 0 in the initialized state), and registers the name of the function declared in the noticed function declaration part into the field 3211 of this record 3210 (S1402).

Next, the source analysis part 21 searches the source program for call initiation functions that call the function declared in the noticed function declaration part (S1403). In detail, the source analysis part 21 identifies all the function declaration parts of the source program, except the noticed function declaration part. Then, for each identified function declaration part, it is examined whether the identified function declaration part in question calls the function declared in the noticed function declaration part. For example, in the case where the source program is one shown in FIG. 2 and the noticed function declaration part is the part 315, the source analysis part 21 searches for function declaration parts (except for the part 315) that call the function “func1”.

Further, the source analysis part 21 searches the noticed function declaration part for call destination functions, read reference tables and write reference tables (S1404). For example, in the case where the source program is one shown in FIG. 2 and the noticed function declaration part is the part 315, call destination functions are functions “func2” and “func3” described in the 24th and 25th lines, and a read reference table is the table “TBL1” described in the 27th line. A write reference table does not exist in the part 315.

Next, the source analysis part 21 registers the number of the call initiation functions, the number of the call destination functions, the number of the read reference tables and the number of the write reference tables searched for in S1403 and S1404 into the fields 3212-3215 of the record 3210 of function metrics information added in S1402 (S1405).

Then, the source analysis part 21 examines whether the source program has a function declaration part that has not been noticed yet (S1406). In the case where there exists a function declaration part that has not been noticed yet, the flow returns to S1401. Otherwise, the flow proceeds to S1407.

According to the processing of S1401-S1406, a record 3210 of function metrics information is generated for each function declaration part of the source program. As a result, the metrics information storage part 32 stores the function metrics information table 321 as shown in FIG. 3.

Next, in S1407, the source program analysis part 21 detects a table declaration part that has not been noticed yet, from the source program, and determines the detected part as a noticed table declaration part. For example, in the case of the source program shown in FIG. 2, the part 313 declaring the table “TBL1” is first extracted as a noticed table declaration part.

Next, the source analysis part 21 adds a record 3220 to the table metrics information table 322 (the number of records is 0 in the initialized state), and registers the name of the table declared in the noticed table declaration part into the field 3221 of this record 3220 (S1408).

Next, the source analysis part 21 searches the source program for read reference functions for which the table declared in the noticed table declaration part becomes an object of Read Reference and write reference functions for which the table in question becomes an object of Write Reference (S1409). In detail, the source analysis part 21 identifies all the function declaration parts of the source program, and then, for each function declaration part, examines whether the function declaration part in question refers to the table declared in the noticed table declaration part. For example, in the case where the source program is one shown in FIG. 2 and the noticed table declaration part is the part 313, the source analysis part 21 searches for function declaration parts for which the table “TBL1” becomes an object of Read Reference or Write Reference.

Next, the source analysis part 21 registers the numbers of the read reference functions and write reference functions retrieved in S1409 respectively into the fields 3222 and 3223 of the record 3220 of table metrics information added in S1408 (S1410).

Then, the source analysis part 21 examines whether the source program has a table declaration part that has not been noticed yet (S1411). In the case where there exists a table declaration part that has not been noticed yet, the flow returns to S1407. Otherwise, the flow is ended. According to the processing of S1407-S1411, a record 3220 of table metrics information is generated for each table declaration part of the source program. As a result, the metrics information storage part 321 stores the table metrics information table 322 as shown in FIG. 4.

Now, FIG. 10 is referred to again, to continue the description. Next, the source analysis part 21 performs failure report document analysis processing. Namely, the source analysis part 21 analyzes the failure report document data stored in the failure report document storage part 33 to generate a failure information table 341, and stores the generated failure information table 341 into the failure information storage part 34 (S15).

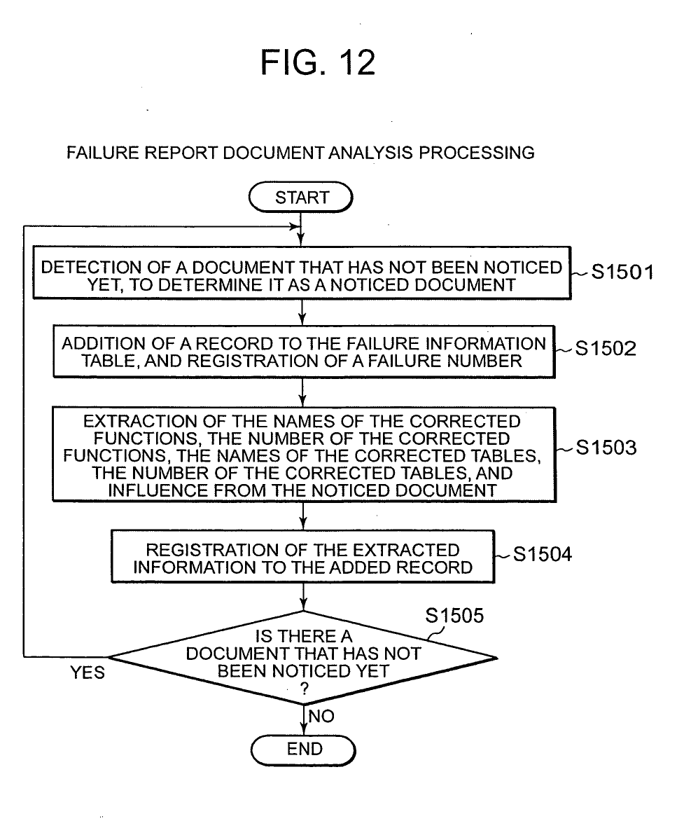

FIG. 12 is a flowchart for explaining the failure report document analysis processing.

First, the document analysis part 22 reads one piece of failure report document data that have not been noticed yet from the failure report document storage part 33, and determines the read data as a noticed document (S1501). Next, the document analysis part 22 adds a record 3410 to the failure information table 341 (the number of records is 0 in the initialized state), and registers a unique failure number (for example, a serial number) into the field 3411 of this record 3410 (S1502).

Next, the document analysis part 22 extracts “influence”, “names of functions corrected”, “number of the functions corrected”, “names of tables corrected” and “number of the tables corrected” registered in the fields 3308-3312 of the noticed document (S1503). For example, in the case where the noticed document is one shown in FIG. 5, “5”, “func1”, “1”, “TBL138 and “1” are extracted as “influence”, “names of functions corrected”, “number of the functions corrected”, “names of tables corrected” and “number of the tables corrected”.

Next, the document analysis part 22 registers “names of functions corrected”, “number of the functions corrected”, “names of tables corrected” and “number of the tables corrected” into the fields 3412-3416 of the record 3410 of failure information added in S1502 (S1504).

Then, the document analysis part 22 examines whether the failure report document storage part 33 stores failure document data that have not been noticed yet (S1505). In the case where the failure report document storage part 33 stores such data, the flow returns to S1501. Otherwise, this flow is ended. According to the above processing, a record 3410 of failure information is generated for each piece of failure report document data stored in the failure report document storage part 33. As a result, the failure information storage part 34 stores the failure information table 341 as shown in FIG. 6.

Now, FIG. 10 is referred to again, to continue the description. Next, the failure correction difficulty analysis part 23 performs failure correction difficulty analysis processing. Namely, the failure correction difficulty analysis part 23 analyzes the metrics information stored in the metrics information storage part 32 and the failure information stored in the failure information storage part 34 to generate a failure correction difficulty information table 351, and stores the generated table 351 into the failure correction difficulty information storage part 35 (S16).

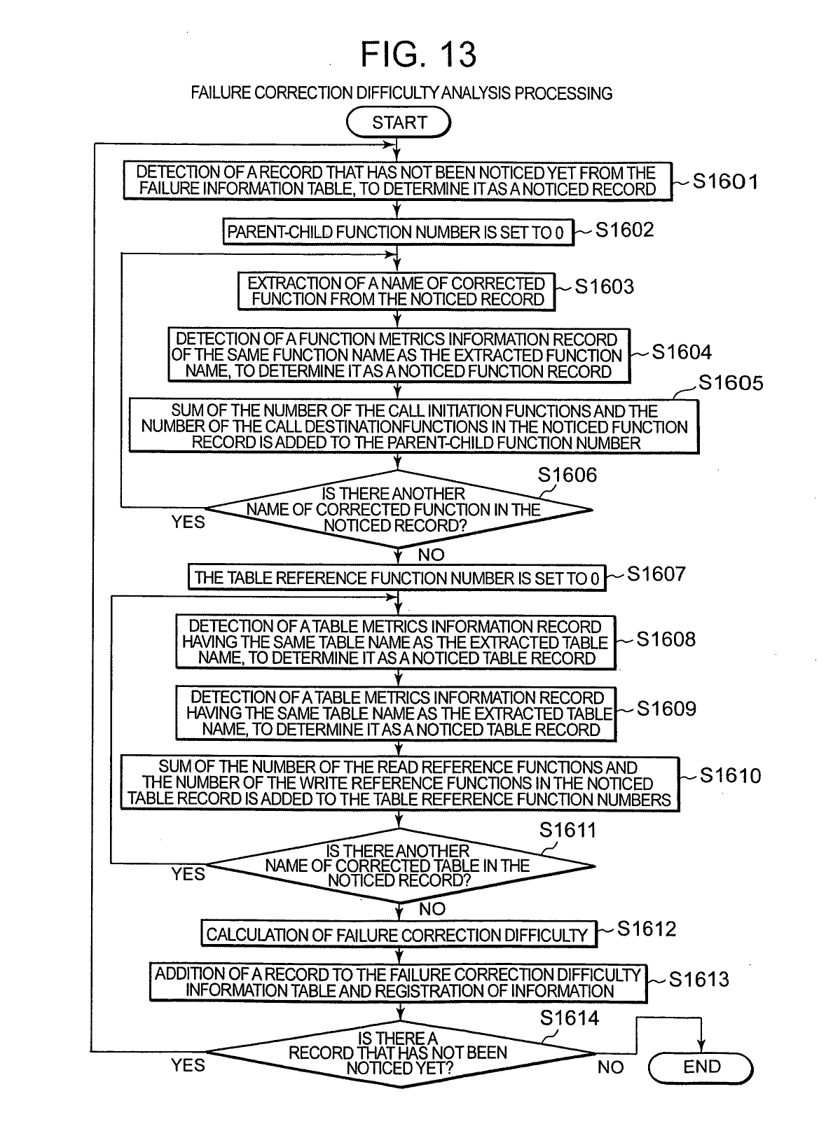

FIG. 13 is a flowchart for explaining the failure correction difficulty analysis processing.

First, the failure correction difficulty analysis part 23 detects a failure information record 3410 that has not been noticed yet, from the failure information table 341 stored in the failure information storage part 34, and determines the detected record as a noticed record (S1601). Next, the failure correction difficulty analysis part 23 initializes a parent-child function number that indicates the number of functions in parent-child relationship with the functions corrected to cope with the failure corresponding to the noticed record 3410, whereby the parent-child function number is set to zero (S1602). Next, from the field 3412 of the noticed record 3410, the failure correction difficulty analysis part 23 extracts one “name of the function corrected” that has not been extracted yet (S1603). For example, in the case where the record 3410 having the failure number “2” shown in FIG. 6 is the noticed record, either the function “func1” or the function “func2” is extracted. Then, the failure correction difficulty analysis part 23 detects a function metrics information record 3210 having the field 3211 that registers the same function name as the extracted “name of the function corrected”, from the function metrics information table 3210 stored in the metrics information storage part 32. And, the detected record 3210 is determined as a noticed function record (S1604). Then, the failure correction difficulty analysis part 23 obtains the sum of the number of the call initiation functions and the number of the call destination functions registered in the fields 3212 and 3213 of the noticed function record, and adds this sum to the parent-child function number (S1605). For example, in the case where the record 3210 having the function name “func1” shown in FIG. 3 is the noticed function record, the sum “12” of the number of the call initiation functions “10” and the number of the call destination functions “2” is added to the parent-child function number.

Then, the failure correction difficulty analysis part 23 examines whether there exists a “name of a function corrected” that has not been extracted yet in the field 3412 of the noticed record 3410 (S1606). In the case where there exists such a function name, the flow returns to S1603. Otherwise, the flow proceeds to S1607.

In S1607, the failure correction difficulty analysis part 23 initializes a table reference function number that indicates the number of functions referring to the tables corrected to cope with the failure corresponding to the noticed record 3410, whereby the table reference function number is set to zero. Next, from the field 3414 of the noticed record 3410, the failure correction difficulty analysis part 23 extracts one “name of the table corrected” that has not been extracted yet (S1608). For example, in the case where the record 3410 having the failure number “2” shown in FIG. 6 is the noticed record, either the table “TBL1” or the table “TBL2” is extracted. Then, the failure correction difficulty analysis part 23 detects a table metrics information record 3220 having the field 3221 that registers the same table name as the extracted “name of the table corrected”, from the table metrics information table 322 stored in the metrics information storage part 32, and determines the detected record 3220 as a noticed table record (S1609). Then, the failure correction difficulty analysis part 23 obtains the sum of the number of the read reference functions and the number of the write reference functions registered in the fields 3222 and 3223 of the noticed table record, and adds this sum to the table reference function numbers (S1610). For example, in the case where the record 3220 having the table name “TBL1” shown in FIG. 4 is the noticed table record, the sum “5” of the number of the read reference functions “3” and the number of the write reference functions “2” is added to the table reference function number.

Now, the failure correction difficulty analysis part 23 examines whether there exists a “name of a table corrected” that has not been extracted in the field 3414 of the noticed record 3410 (S1611). In the case where there exists such a table name, the flow returns to S1608. Otherwise, the flow proceeds to S1612.

In S1612, the failure correction difficulty analysis part 23 calculates the sum of the parent-child function number and the table reference function number obtained according to the above processing, and determines the obtained sum as failure correction difficulty for indicating difficulty in coping with the failure corresponding to the noticed record 3410. Then, the failure correction difficulty analysis part 23 adds a record 3510 to the failure correction difficulty information table 351, and registers the failure number registered in the field 3411 of the noticed record 3410 into the field 3511, the failure correction difficulty calculated in S1612 into the field 3512, and the influence registered in the field 3416 of the noticed record into the field 3513 (S1613).

Then, the failure correction difficulty analysis part 23 examines whether there exists a failure information record that has not been noticed yet in the failure information table 341 (S1614). In the case where there exists a record that has not been noticed yet, the flow returns to S1601. Otherwise, this flow is ended. As a result, the failure correction difficulty information storage part 35 stores the failure correction difficulty information table 351 as shown in FIG. 7.

Here, FIG. 10 is referred to again, to continue the description. Next, the importance determination part 24 performs importance determination processing. Namely, the importance determination part 24 analyzes the metrics information stored in the metrics information storage part 32 and the failure correction difficulty information stored in the failure correction difficulty information storage part 35 to generate a function importance table 361, and stores the generated function importance table 361 into the knowledge information storage part 36 (S17).

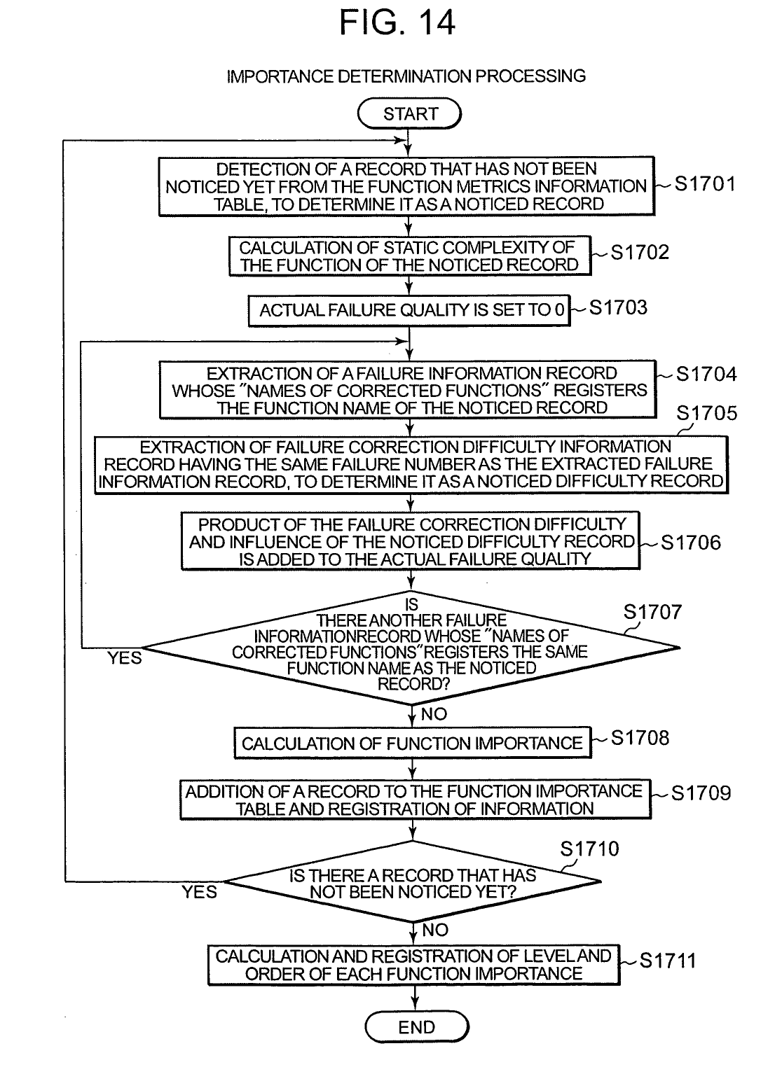

FIG. 14 is a flowchart for explaining the importance determination processing.

First, the importance determination part 24 detects a function metrics information record 3210 that has not been noticed yet from the function metrics information table 321 stored in the metrics information storage part 32, and determines the detected record as a noticed record (S1701). Next, the importance determination part 24 calculates the sum of “the number of the call initiation functions”, “the number of the call destination functions”, “the number of the read reference tables” and “the number of write reference tables” registered in the fields 3212-3215 of the noticed record 3210, and determines this sum as static complexity that indicates intensity of the relationship of the function of the noticed record with other functions and tables (S1702). For example, in the case where the notice record is the record 3210 having the function name “func1” shown in FIG. 3, the sum “13” of the number of the call initiation functions “10”, the number of the call destination functions “2”, the number of the read reference table “1” and the number of the write reference table “0” becomes the static complexity.

Next, the importance determination part 24 initializes actual failure quality that indicates influence of the failure against which the function of the noticed record 3210 has been corrected as a countermeasure and difficulty of that countermeasure, whereby the actual failure quality is set to zero (S1703). Then, from the failure information table 341 stored in the failure information storage part 34, the importance determination part 24 extracts one failure information record 3410 that has the field 3412 registering, as the “name of the function corrected”, the “function name” registered in the field 3211 of the noticed record 3210 and that has not been extracted yet (S1704). For example, in the case where the noticed record is the record 3210 having the function name “func1” shown in FIG. 3, the importance determination part 24 extracts a failure information record 3410 whose failure number is “1” or “2” in FIG. 6.

Then, the importance determination part 24 detects the failure correction difficulty information record 3510 whose field 3511 registers the failure number registered in the field 3411 of the extracted failure information record 3410, and determines the detected record 3510 as a noticed difficulty record (S1705). For example, in the case where the record 3410 having the failure number “1” shown in FIG. 6 is extracted in S1704, the failure correction difficulty information record 3510 having the failure number “1” in FIG. 7 is determined as the noticed difficulty record.

Next, the importance determination part 24 calculates the product of the failure correction difficulty and the influence registered respectively in the fields 3512 and 3513 of the noticed difficulty record, and adds the calculated product to the actual failure quality (S1706). For example, in the case where the noticed difficulty record is the record 3510 having the failure number “1” shown in FIG. 7, the product “85” of the failure correction difficulty “17” and the influence “5” is added to the actual failure quality.

Then, the importance determination part 24 examines whether there exists a failure information record 3410 that has the field 3412 registering, as the “name of the function corrected”, the “function name” registered in the field 3211 of the noticed record and that has not been extracted yet (S1707). In the case where there exists such a record 3410, the flow returns to S1704. Otherwise, the flow proceeds to S1708. In S1708, the importance determination part 24 calculates the product of the actual failure quality and the static complexity obtained in S1702, and determines the calculated product as function importance of the function of the noticed record 3210. The function importance indicates the size of program development man-hours to be allocated to the function concerned. Next, the importance determination part 24 adds a record 3610 to the function importance table 361 (the number of records is 0 in the initialized state), and registers the function name of the noticed record into the field 3611 of this record 3610, and the function importance calculated in S1708 into the field 3612 (S1709).

Then, the importance determination part 24 examines whether there exists a function metrics information record 3210 that has not been noticed yet in the function metrics information table 321 (S1710). In the case where there exists such a record, the flow returns to S1701. Otherwise, the flow proceeds to S1711.

In S1711, the importance determination part 24 sorts the records 3610 in the function importance table 361 in the descending order of the function importance registered in the field 3612 of each record 3610, and registers the order into the field 3614 of each record 3610. Further, the importance determination part 24 registers a level into the field 3613 of each record, according to a certain rule. For example, the records 3610 of the function importance table 361 are classified into five levels (levels A, B, C, D and E, with A being the most important level and E the least important level) according to the magnitude of the function importance, and the level of each record is registered. Thereafter, the flow is ended.

As described above, the function importance table 361 as shown in FIG. 8 is stored into the knowledge information storage part 36. Thus, it is possible to determine the function importance (which can be hardly determined when the source program shown in FIG. 2 is simply observed) for each function in the source program. For example, in the case of the source program shown in FIG. 2, the function “func2” has a large number of function call statements and table reference statements, and thus the function “func2” seems to have the largest importance. However, considering the past failure reports, it is found that the function “func1” has the largest importance. Thus, it is possible to obtain information that can not be grasped by looking at the source program only.

The description will be continued referring to FIG. 10 again. When the function importance table 361 is generated in the knowledge information storage part 36, the input/output part 1 outputs the contents of the function importance table 361 together with, for example, the contents of the function metrics information table 321 and the table metrics information table 322 stored in the metrics information storage part 32, to present the function importance of each function in the source program to the user (S18).

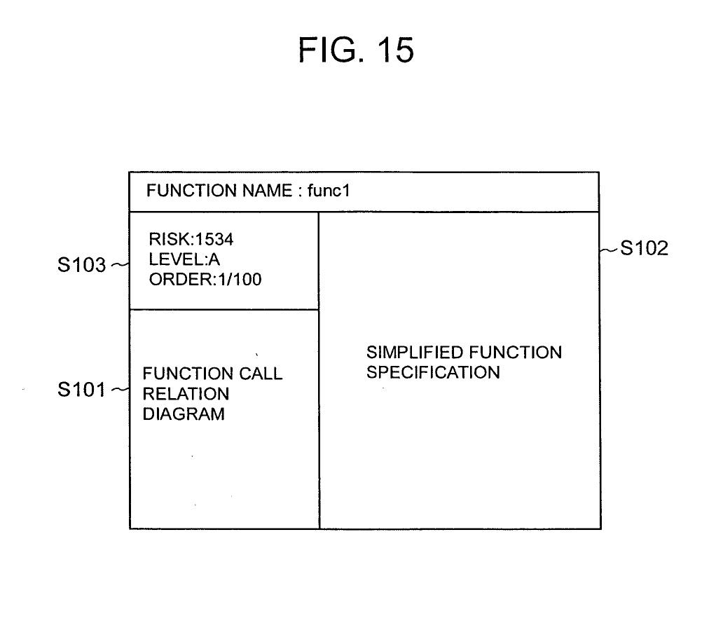

For example, for each function whose record 3610 is registered in the function importance table 361, the function importance is shown on a display. FIG. 15 is an example of screen display of function importance. In this example, with respect to the function “func1”, are displayed a function call relation diagram 101 and a simplified function specification 102 generated employing the re-engineering (See, for example, the above-mentioned Patent Document 1), as well as information (the function importance, level and order) 103 of the record 3610 whose field 3611 registers the function “func1” in the function importance table 361. The order may be displayed by the side of the total number of functions of the source program. Then, it becomes easy to grasp the function importance (order/total number of functions).

The above-mentioned function call relation diagram is a graph showing static function call relationships between functions. Further, the simplified function specification is a table showing information such as a function name, operation of the function, names of arguments, meanings of the arguments, and the like obtained from the source program and its comments. Information required for generating the function call relation diagram and the simplified function specifications may be detected when the source analysis part 21 analyzes the source program, and stored, for each function, into the metrics information storage part 32.

Hereinafter, one embodiment of the present invention has been described.

According to the above embodiment, function importance of each function of a program is outputted. Thus, a user (a program developer) can refer to the function importance, and design a program by allocating more man-hours to more important parts of the program (i.e., parts that have higher error frequencies or that largely affect other parts when they are modified) in comparison with less important parts. As a result, it is possible with the same man-hours to decrease failures that has large influence, in comparison with the conventional techniques. As a result, it is possible to develop a high quality program. Further, in the case where there are two or more methods of correcting a failure and each method corrects a different part of the program, it is possible to select a method that corrects less important part. As a result, it is possible to previously reduce a probability of failure occurrence of an important failure. As a result, the total man-hours of development and maintenance can be reduced.

Having described the preferred embodiment of the invention with reference to the accompanying drawings, it is to be understood that the invention is not limited to the above embodiment and that various changes and modifications could be effected therein by one skilled in the art without departing from the spirit or scope of the invention as defined in the appended claims. For example, in S1612 of the failure correction difficulty analysis processing shown in FIG. 13, it is possible to calculate the sum of the product of the parent-child function number and a certain weight (for example, 1) and the product of the table reference function number and a certain weight (for example, 2), and to determine the sum as failure correction difficulty. Thus, by suitably weighting the parent-child function number and the table reference function number, it is possible to calculate more accurate failure correction difficulty. Weighting may be determined by a project leader considering past experiences, or based on correlation with importance of actually-occurred failures.

What is claimed is:

1. A program development support system, which supports development of a program, comprising:
a metrics information storing means that stores metrics information for each part of the program, said metrics information indicating complexity of said part in relation to other parts of the program;
a failure information storing means that stores failure information for each failure occurring in said program, said failure information indicating a corrected part of the program to cope with the failure and influence of the failure on a program user;
an operation means that determines importance of each part of the program, using the complexity indicated by the metrics information of the part in question and the influence indicated by the failure information of each failure against which said part is to be corrected as a countermeasure, said importance indicating a size of program development man-hours to be allocated to said part; and
an importance output means that outputs the importance determined by said operation means for each part of the program.

2. A program development support system according to claim 1, further comprising:
a source program input means into which a source program is inputted;
a source program storing means that stores said source program inputted into said source program input means; and
a source program analysis means that searches, with respect to each part of the source program stored in said source program storing means, for other program parts referred to by said part in question and other program parts referring to the part in question, determines the complexity of the part in question according to a number of said other program parts, and stores the metrics information of the part in question into said metrics information storing means.

3. A program development support system according to claim 1, further comprising:
a document input means into which failure report document data including failure information are inputted;
a failure report document data storing means that stores the failure report document data inputted into said document input means; and
a document analysis means that extracts, for each failure whose failure report document data are stored in said failure report document data storing means, the failure information from said failure report document data of the failure in question, and stores the extracted failure information in association with said failure into said failure information storing means.

4. A program development support system according to claim 2, further comprising:
a document input means into which failure report document data including failure information;
a failure report document data storing means that stores the failure report document data inputted into said document input means; and
a document analysis means that extracts, for each failure whose failure report document data are stored in said failure report document data storing means, the failure information from said failure report document data of the failure in question, and stores the extracted failure information in association with said failure into said failure information storing means.

5. A program development support system according to claim 1, wherein:
said operation means comprises:
a failure correction difficulty calculation means that calculates, for each failure whose failure information is stored in said failure information storing means, failure correction difficulty according to complexity indicated by said metrics information of each part (of said program) corrected to cope with the failure in question; and
an importance determination means that determines, for each part (of said program) whose metrics information is stored in said metrics information storing means, importance of the part in question, based on the complexity indicated by the metrics information of said part, the failure correction difficulty of each failure against which the part in question has been corrected as a countermeasure, and the influence indicated by said failure information.

6. A program development support system according to claim 5, further comprising:
a source program input means into which a source program is inputted;
a source program storing means that stores said source program inputted into said source program input means; and
a source program analysis means that searches, with respect to each part of the source program stored in said source program storing means, for other program parts referred to by said part in question and other program parts referring to the part in question, determines the complexity of the part in question according to a number of said program parts, and stores the metrics information of the part in question into said metrics information storing means.

7. A program development support system according to claim 5, further comprising:
a document input means into which failure report document data including failure information are inputted;
a failure report document data storing means that stores the failure report document data inputted into said document input means; and
a document analysis means that extracts, for each failure whose failure report document data are stored in said failure report document data storing means, the failure information from said failure report document data of the failure in question, and stores the extracted failure information in association with said failure into said failure information storing means.

8. A program development support system according to claim 6, further comprising:
a document input means into which failure report document data including failure information;
a failure report document data storing means that stores the failure report document data inputted into said document input means; and
a document analysis means that extracts, for each failure whose failure report document data are stored in said failure report document data storing means, the failure information from said failure report document data of the failure in question, and stores the extracted failure information in association with said failure into said failure information storing means.

9. A program development support system according to claim 5, wherein:
said failure correction difficulty calculation means calculates the failure correction difficulty by changing a weight of the complexity indicated by the metrics information for each part (of said program) corrected to cope with a failure, based on whether the part in question is a function or a table.

10. A program development support system according to claim 9, further comprising:
a source program input means into which a source program is inputted;
a source program storing means that stores said source program inputted into said source program input means; and
a source program analysis means that searches, with respect to each part of the source program stored in said source program storing means, for other program parts referred to by said part in question and other program parts referring to the part in question, determines the complexity of the part in question according to a number of said program parts, and stores the metrics information of the part in question into said metrics information storing means.

11. A program development support system according to claim 9, further comprising:
a document input means into which failure report document data including failure information are inputted;
a failure report document data storing means that stores the failure report document data inputted into said document input means; and
a document analysis means that extracts, for each failure whose failure report document data are stored in said failure report document data storing means, the failure information from said failure report document data of the failure in question, and stores the extracted failure information in association with said failure into said failure information storing means.

12. A program development support system according to claim 10, further comprising:
a document input means into which failure report document data including failure information are inputted;
a failure report document data storing means that stores the failure report document data inputted into said document input means; and
a document analysis means that extracts, for each failure whose failure report document data are stored in said failure report document data storing means, the failure information from said failure report document data of the failure in question, and stores the extracted failure information in association with said failure into said failure information storing means.

13. A program development support method, in which a computer supports development of a program, wherein:
a storage unit of said computer stores metrics information for each part of the program and failure information for each failure occurring in said program, with said metrics information indicating complexity of said part in relation to other parts of the program, and said failure information indicating a corrected part of the program to cope with the failure and influence of the failure on a program user; and
an operation unit of said computer executes:
a step of determining importance of each part of the program, using the complexity indicated by the metrics information of the part in question and the influence indicated by the failure information of each failure against which said part is to be corrected as a countermeasure, said importance indicating a size of program development man-hours to be allocated to said part; and
a step of outputting the determined importance of each part of the program through an output unit of said computer.

14. A program that is readable for a computer and supports development of a program, wherein:
a storage unit of said computer stores metrics information for each part of the program as a development support object (referred to the development support object program) and stores failure information for each failure occurring in said development support object program, with said metrics information indicating complexity of said part in relation to other parts of the development support object program, and said failure information indicating a corrected part of said program to cope with the failure and influence of the failure on a program user; and
said program readable for said computer makes said computer function:
as an operation means that determines importance of each part of the program, using the complexity indicated by the metrics information of the part in question and the influence indicated by the failure information of each failure against which said part is to be corrected as a countermeasure, said importance indicating a size of program development man-hours to be allocated to said part, and
as an importance output means that outputs the importance determined by said operation means for each part of the program, through an output unit of said computer.
